(19) United States
(12) Patent Application Publication
(10) Pub. No.: US 2024/0429676 A1
(43) Pub. Date: Dec. 26, 2024

(54) OPTICAL MODULE

(71) Applicant: SUMITOMO ELECTRIC INDUSTRIES, LTD., Osaka (JP)

(72) Inventors: Yasutaka MIZUNO, Osaka (JP); Tomoya SAEKI, Osaka (JP); Katsumi UESAKA, Osaka (JP); Kotaro HIROSE, Osaka (JP); Masahiro ADACHI, Osaka (JP)

(21) Appl. No.: 18/743,687

(22) Filed: Jun. 14, 2024

(30) Foreign Application Priority Data
Jun. 20, 2023 (JP) 2023-100647
Jun. 20, 2023 (JP) 2023-100648

(51) Int. Cl. H01S 5/024

(52) U.S. Cl. CPC H01S 5/02469

(57) ABSTRACT

An optical module includes a temperature buffer member having a first surface and a second surface opposite to the first surface; an optical semiconductor element that is connected to the first surface and that generates heat by itself; and a heat dissipation member connected to the second surface. The temperature buffer member is formed of a phase transformation material, a thermal conductivity of the phase transformation material changing at a phase transformation temperature.

### CROSS-REFERENCE TO RELATED APPLICATIONS

This patent application is based on and claims priority to Japanese Patent Application No. 2023-100647 filed on Jun. 20, 2023, and Japanese Patent Application No. 2023-100648 filed on Jun. 20, 2023, the entire contents of which are incorporated herein by reference.

### TECHNICAL FIELD

The present disclosure relates to an optical module.

### BACKGROUND

Japanese Laid-open Patent Application Publication No. 2001-094200 (Patent Document 1) discloses a semiconductor laser module that includes a semiconductor laser and controls the wavelength of light emitted from the semiconductor laser. Patent Document 1 discloses that in the semiconductor laser module, the wavelength is controlled by a heating element with no Peltier cooling.

Japanese Laid-open Patent Application Publication No. 2018-160520 (Patent Document 2) discloses a submount having a mounting surface on which three or more semiconductor laser elements are mounted to be arranged side by side in a first direction. Patent Document 2 discloses that the submount includes a heating element for increasing the temperature of the three or more semiconductor laser elements.

### SUMMARY

One aspect of the present disclosure is an optical module including a temperature buffer member having a first surface and a second surface opposite to the first surface; an optical semiconductor element that is connected to the first surface and that generates heat by itself; and a heat dissipation member connected to the second surface. The temperature buffer member is formed of a phase transformation material, a thermal conductivity of the phase transformation material changing at a phase transformation temperature.

Another aspect of the present disclosure is an optical module including a temperature buffer member having a first surface and a second surface opposite to the first surface; an optical semiconductor element connected to the first surface; a heater member connected to the first surface and configured to generate heat by receiving electric power from outside; and a heat dissipation member connected to the second surface. The temperature buffer member is formed of a phase transformation material, a thermal conductivity of the phase transformation material changing at a phase transformation temperature.

### BRIEF DESCRIPTION OF THE DRAWINGS

FIG. 1 is a perspective view schematically illustrating an optical module according to a first embodiment;

FIG. 2 is a view for explaining a use state of the optical module according to the first embodiment;

FIG. 3 is a graph for explaining the temperature of a temperature buffering member included in the optical module;

FIG. 4 is a graph for explaining the thermal resistance of the temperature buffer member included in the optical module;

FIG. 5 is a graph for explaining an operation result of the optical module according to the first embodiment;

FIG. 6 is a graph for explaining the operation result of the optical module according to the first embodiment;

FIG. 7 is a graph for explaining the operation result of the optical module according to the first embodiment;

FIG. 8 is a graph for explaining the operation result of the optical module according to the first embodiment;

FIG. 9 is a perspective view schematically illustrating an optical module according to a second embodiment;

FIG. 10 is a view for explaining a use state of the optical module according to the second embodiment;

FIG. 11 is a diagram for explaining an outline of a functional configuration of the optical module according to the second embodiment;

FIG. 12 is a graph for explaining an operation result of the optical module according to the second embodiment; and

FIG. 13 is a view for explaining a modified example of the optical module according to the second embodiment.

### DETAILED DESCRIPTION OF EMBODIMENTS

### Problem to be Solved by the Present Disclosure

In an optical module, it is desirable to maintain the temperature of the optical semiconductor element within a predetermined range (to adjust the temperature) with low power consumption.

### Effects of the Invention

According to the optical module of the present disclosure, the temperature of the optical semiconductor element can be maintained within a predetermined range (can be adjusted) with low power consumption.

### DESCRIPTION OF EMBODIMENTS OF THE PRESENT DISCLOSURE

First, embodiments of the present disclosure will be listed and described.

(1) An optical module of the present disclosure includes a temperature buffer member having a first surface and a second surface opposite to the first surface; an optical semiconductor element that is connected to the first surface and that generates heat by itself; and a heat dissipation member connected to the second surface. The temperature buffer member is formed of a phase transformation material, and a thermal conductivity of the phase transformation material changes at a phase transformation temperature.

According to the optical module of the present disclosure, the temperature of the optical semiconductor element can be maintained within a predetermined range with low power consumption.

(2) In (1) described above, a thermal conductivity of the heat dissipation member may be larger than a thermal conductivity of the temperature buffer member. This is because the change in the temperature of the optical semiconductor element due to the phase transformation material can be relatively increased by increasing the thermal conductivity of the heat dissipation member.

(3) In (1) or (2) described above, the first surface may have a first temperature higher than the phase transformation temperature when the temperature of the second surface is equal to the phase transformation temperature. Additionally, the second surface may have a second temperature lower than the phase transformation temperature when the temperature of the first surface is equal to the phase transformation temperature. Further, a first temperature difference between the first temperature and the phase transformation temperature may be set to be smaller than a second temperature difference between the phase transformation temperature and the second temperature. This is to promote heat dissipation when the temperature of the optical semiconductor element is high.

(4) In (3) described above, the first temperature may be set to a temperature lower than an upper limit operating temperature of the optical semiconductor element. This is because the optical semiconductor element can be stably operated.

(5) In (3) or (4) described above, the temperature buffer member may have a first thermal resistance between the first surface and the second surface when the temperature of the second surface is equal to the phase transformation temperature. Additionally, the temperature buffer member may have a second thermal resistance between the first surface and the second surface, the second thermal resistance being larger than the first thermal resistance, when the temperature of the second surface is equal to the second temperature. This is because the optical semiconductor element can be stably operated.

(6) In (5) described above, a resistance value of the second thermal resistance may be greater than twice a resistance value of the first thermal resistance. This is because the optical semiconductor element can be stably operated.

(7) In any one of (1) to (6) described above, the phase transformation temperature of the phase transformation material may be 70° C. or greater and 100° C. or less. This is to promote heat dissipation when the temperature of the optical semiconductor element is high.

(8) In any one of (1) to (7) described above, the phase transformation material may include any one of silver sulfide, a silver chalcogenide, or copper gallium telluride. This is because the temperature of the optical semiconductor element can be maintained within a predetermined range with low power consumption.

(9) In any one of (1) to (8) described above, any one of heat dissipation grease, solder, or metal paste may be further provided between the second surface of the temperature buffer member and the heat dissipation member. This is because the heat transfer efficiency between the temperature buffer member and the heat dissipation member can be improved.

(10) An optical module of the present disclosure includes a temperature buffer member having a first surface and a second surface opposite to the first surface, an optical semiconductor element connected to the first surface, a heater member connected to the first surface and configured to generate heat by receiving electric power from the outside, and a heat dissipation member connected to the second surface. The temperature buffer member is formed of a phase transformation material, and a thermal conductivity of the phase transformation material changes at a phase transformation temperature.

According to the optical module of the present disclosure, the temperature of the optical semiconductor element can be adjusted with low power consumption.

(11) In (10) described above, a thermal conductivity of the heat dissipation member may be larger than a thermal conductivity of the temperature buffer member. This is because the temperature rise of the optical semiconductor element can be suppressed and the temperature can be adjusted to a desired value by increasing the thermal conductivity of the heat dissipation member.

(12) In (10) or (11) described above, the first surface may have a first temperature higher than the phase transformation temperature when the temperature of the second surface is equal to the phase transformation temperature. Additionally, the temperature of the first surface may be maintained at the first temperature by adjusting the electric power of the heater member when the temperature of the second surface is lower than the phase transformation temperature. This is because the temperature of the optical semiconductor element can be adjusted with low power consumption.

(13) In (12) described above, the first temperature may be set to a temperature lower than an upper limit operating temperature of the optical semiconductor element. This is because the optical semiconductor element can be stably operated.

(14) In any one of (10) to (13) described above, the second surface may have a second temperature lower than the phase transformation temperature when the temperature of the first surface is equal to the phase transformation temperature. Additionally, the temperature buffer member may have a first thermal resistance between the first surface and the second surface when the temperature of the second surface is equal to the phase transformation temperature, and may have a second thermal resistance between the first surface and the second surface, the second thermal resistance being larger than the first thermal resistance, when the temperature of the second surface is equal to the second temperature. This is to promote heat dissipation when the temperature of the optical semiconductor element is high.

(15) In (14) described above, a resistance value of the second thermal resistance may be greater than twice a resistance value of the first thermal resistance. This is because the optical semiconductor element can be stably operated.

(16) In any one of (10) to (15) described above, the phase transformation temperature of the phase transformation material may be 70° C. or greater and 100° C. or less. This is to promote heat dissipation when the temperature of the optical semiconductor element is high.

(17) In any one of (10) to (16) described above, the phase transformation material may include any one of silver sulfide, a silver chalcogenide, or copper gallium telluride. This is because the temperature of the optical semiconductor element can be adjusted with low power consumption.

(18) In any one of (10) to (17), a temperature detection element connected to the first surface and configured to generate a detection signal in accordance with the temperature of the first surface may be included. This is because the temperature of the optical semiconductor element can be adjusted with low power consumption.

### Details of Embodiments of the Present Disclosure

Specific examples of the optical module of the present disclosure will be described below with reference to the drawings. Here, the present invention is not limited to these examples, but is intended to be defined by the scope of the claims, and to include all modifications within the meaning and scope equivalent to the scope of the claims.

In the description of the specification and the drawings according to each embodiment, components having substantially the same or corresponding functions are denoted by the same reference symbols, and a duplicated description thereof may be omitted. Additionally, for ease of understanding, the scale of each part in the drawings may be different from the actual scale.

The embodiments will be described below, but at least a part of the embodiments described below may be suitably combined.

An optical module according to a first embodiment includes a temperature buffer member having a first surface and a second surface opposite to the first surface, an optical semiconductor element that is connected to the first surface and that generates heat by itself, and a heat dissipation member connected to the second surface. The temperature buffer member in the optical module according to the first embodiment is formed of a phase transformation material, and a thermal conductivity of the phase transformation material changes at a phase transformation temperature.

### Configuration of Optical Module According to First Embodiment

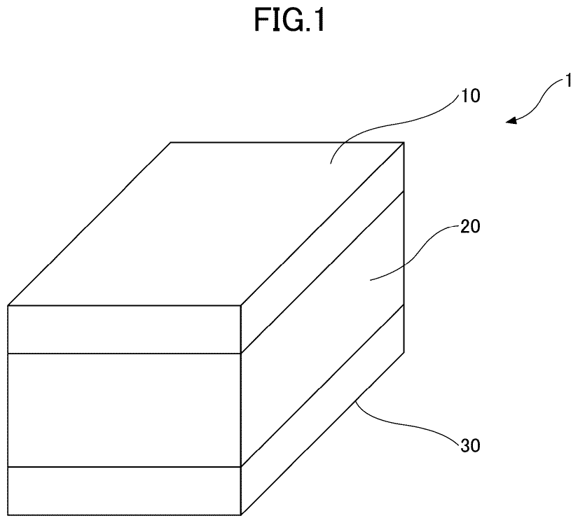

The optical module according to the first embodiment will be described using a specific example. FIG. 1 is a perspective view schematically illustrating an optical module 1, which is an example of the optical module according to the first embodiment.

The optical module 1 includes an optical semiconductor element 10, a temperature buffer member 20, and a heat dissipation member 30.

### [Optical Semiconductor Element 10]

The optical semiconductor element 10 is an element including a semiconductor configured to convert light and electricity. Additionally, the optical semiconductor element 10 generates heat by itself. The optical semiconductor element 10 is, for example, a laser diode. The laser diode generates heat in emitting light.

For example, the oscillation wavelength of laser diode changes at a rate of 0.1 nm/° C. depending on the operating temperature. Thus, it is necessary to keep the laser diode within a predetermined temperature range, particularly in wavelength division multiplex communications.

Here, although an example in which a laser diode is used as the optical semiconductor element 10 will be described, the optical semiconductor element 10 is not limited to a laser diode, and may be, for example, a light emitting diode (LED). The optical semiconductor element 10 may be an electro-absorption modulator integrated laser in which a laser diode that outputs continuous light and an electro absorption modulator that modulates the continuous light are integrated on one semiconductor chip. Additionally, the optical semiconductor element 10 is not limited to a light emitting element, and can be applied to all optical semiconductor elements that require temperature adjustment.

### [Temperature Buffer Member 20]

The temperature buffer member 20 is a member whose thermal resistance changes depending on the temperature. The temperature buffer member 20 is formed of, for example, a phase transformation material whose thermal conductivity changes at a phase transformation temperature. The phase transformation material includes, for example, any one of silver sulfide, a silver chalcogenide, or copper gallium telluride. The temperature buffer member 20 preferably has a phase transformation temperature of, for example, 70° C. or greater and 100° C. or less in consideration of the operation range of the optical module 1 and the like. Here, the thermal resistance herein is a thermal resistance when heat generated in the optical semiconductor element 10 is transmitted to the heat dissipation member 30 via the temperature buffer member 20.

The phase transformation material forming the temperature buffer member 20 is a material whose state changes between a high temperature phase and a low temperature phase at a phase transformation temperature. For example, the thermal conductivity when the phase transformation material is in the high temperature phase is different from the thermal conductivity when the phase transformation material is in the low temperature phase. In other words, the thermal resistance when the phase transformation material is in the high temperature phase is different from the thermal resistance when the phase transformation material is in the low temperature phase. The phase transformation material forming the temperature buffer member 20 may include an intermediate phase having an intermediate property between the high temperature phase and the low temperature phase near the phase transformation temperature.

As the phase transformation material, for example, a silver chalcogenide containing sulfur and selenium may be used. More specifically, any one of Ag₂S_{0.2}Se_{0.8}, Ag₂S_{0.4}Se_{0.6}, Ag₂S_{0.6}Se_{0.4}, or Ag₂S_{0.8}Se_{0.2}, which is a silver chalcogenide, may be used as the phase transformation material.

The silver chalcogenide is solid in a use temperature range in the optical module 1, for example, in a temperature range from −20° C. to 80° C. Additionally, in the silver chalcogenide, chalcogen atoms form a cubic lattice in the high temperature phase. In the silver chalcogenide, silver atoms easily move in the high temperature phase. That is, the silver chalcogenide becomes a superionic conductor in the high temperature phase. Furthermore, the thermal conductivity of the silver chalcogenide greatly changes with the transformation from the low temperature phase to the high temperature phase. Additionally, the thermal conductivity of the silver chalcogenide greatly changes in a narrow temperature range.

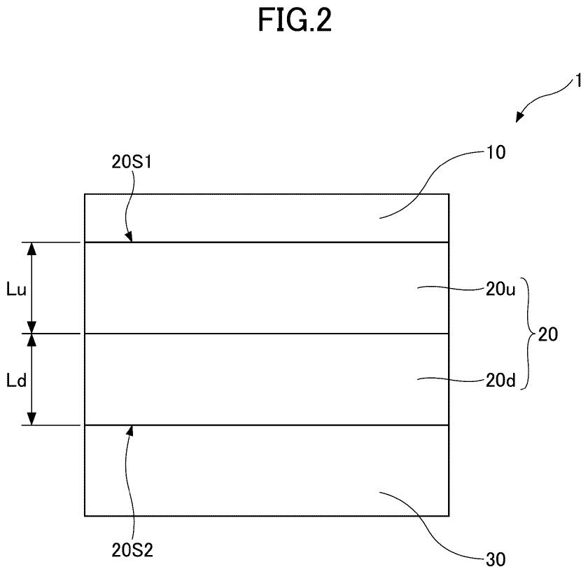

The temperature buffer member 20 has a first surface 201 (see FIG. 2) and a second surface 20S2 (see FIG. 2) provided opposite to the first surface 20S1. The optical semiconductor element 10 is connected to the first surface 201. The heat dissipation member 30 is connected to the second surface 20S2. Therefore, the heat generated in the optical semiconductor element 10 conducts through the temperature buffer member 20 from the first surface 20S1 toward the second surface 20S2, and is transmitted to the heat dissipation member 30. When the above-described thermal resistance becomes relatively large, the amount of heat that conducts from the first surface 20S1 to the second surface 20S2 decreases, and when the above-described thermal resistance becomes relatively small, the amount of heat that conducts from the first surface 20S1 to the second surface 20S2 increases. Here, when the heat dissipation member 30 is connected to the temperature buffer member 20, any one of heat dissipation grease, solder, or metallic paste may be further provided between the second surface 20S2 and the heat dissipation member 30. This can reduce the thermal resistance between the second surface 20S2 and the heat dissipation member 30. With respect to the dissipation of the heat generated in the optical semiconductor element 10, it is preferable that the thermal resistance between the second surface 20S2 and the heat dissipation member 30 is small.

### [Heat Dissipation Member 30]

The heat dissipation member 30 dissipates the heat generated in the optical semiconductor element 10 to the outside. The heat dissipation member 30 is formed of, for example, metal. The heat dissipation member 30 is formed of, for example, aluminum nitride. The heat dissipation member 30 may be, for example, a part of a body that accommodates the optical semiconductor element 10.

The thermal conductivity of the heat dissipation member 30 may be greater than the thermal conductivity of the temperature buffer member 20. By making the thermal conductivity of the heat dissipation member 30 greater than the thermal conductivity of the temperature buffer member 20, the operating temperature of the optical semiconductor element 10 can be lowered when the thermal conductivity of the phase transformation material of the temperature buffer member 20 is great. Generally, the upper limit is defined for the operating temperature of the optical semiconductor element 10, and it is preferable to efficiently dissipate the generated heat to the outside to lower the operating temperature.

The heat dissipation member 30 preferably has sufficient heat capacity and heat dissipation capability in order to reduce an increase in the operating temperature of the optical semiconductor element 10 when the heat generated in the optical semiconductor element 10 is dissipated to the outside.

### <Temperature Characteristics of Optical Module According to First Embodiment>

A temperature characteristic of the optical module according to the first embodiment will be described using the optical module 1, which is the example of the optical module according to the first embodiment. FIG. 2 is a view for explaining a use state of the optical module 1, which is the example of the optical module according to the first embodiment.

In FIG. 2, a case where the temperature (the operating temperature) of the optical semiconductor element 10 is higher than the temperature of the heat dissipation member 30 will be described. When the optical semiconductor element 10 generates heat by itself, the operating temperature becomes higher than the temperature of the heat dissipation member 30. In the configuration in which the temperature buffer member 20 is sandwiched between the optical semiconductor element 10 and the heat dissipation member 30, the heat generated in the optical semiconductor element 10 is transmitted from the optical semiconductor element 10 to the heat dissipation member 30 via the temperature buffer member 20. At this time, a direction in which the heat is transmitted is the same as a direction in which the optical semiconductor element 10, the temperature buffer member 20, and the heat dissipation member 30 are arranged (a first direction).

When the optical module 1 is operated, the optical semiconductor element 10 generates heat by itself, and thus the temperature thereof increases. It is assumed that the heat dissipation member 30 is maintained at a substantially constant temperature. When the thermal resistance between the heat dissipation member 30 and the outside is sufficiently smaller than the thermal resistance of the temperature buffer member 20 and the heat capacity of the heat dissipation member 30 is sufficiently larger than the self-heating amount of the optical semiconductor element 10, for example, a temperature change of the heat dissipation member 30 can be ignored. Here, it is considered that the temperature of the heat dissipation member 30 is substantially equal to the outside temperature (for example, the temperature of a casing of the body or the surrounding environmental temperature around the optical module 1).

The operating temperature of the optical semiconductor element 10 is represented by a temperature Tld, and the temperature of the heat dissipation member 30 is represented by a temperature Tcase. The temperature Tld, which is the operating temperature of the optical semiconductor element 10, is, for example, the temperature of the surface of the optical semiconductor element 10 that is in contact with the first surface 20S1. The temperature Tcase of the heat dissipation member 30 is, for example, the temperature of the surface of the heat dissipation member 30 that is in contact with the second surface 20S2. The phase transformation temperature of the phase transformation material forming the temperature buffer member 20 is represented by a phase transformation temperature Tpt. As the temperature condition, a case where the phase transformation temperature Tpt is higher than the temperature Tcase of the heat dissipation member 30 and lower than the temperature Tld of the optical semiconductor element 10 is assumed.

In the optical module 1, the temperature of the inside of the temperature buffer member 20 (the internal temperature) between the optical semiconductor element 10 and the heat dissipation member 30 is considered to change in accordance with the distance from the optical semiconductor element 10 that generates heat by itself. That is, the internal temperature increases as the position is closer to the optical semiconductor element 10, and decreases as the position is farther from the optical semiconductor element 10. Therefore, as illustrated in FIG. 2, the temperature buffer member 20 is separated into a high temperature layer 20u and a low temperature layer 20d. The high temperature layer 20u is a layer of the temperature buffer member 20 having a temperature higher than the phase transformation temperature Tpt. In other words, the high temperature layer 20u is a layer in which the phase transformation material is in the high temperature phase. The low temperature layer 20d is a layer of the temperature buffer member 20 having a temperature lower than the phase transformation temperature Tpt. In other words, the low temperature layer 20d is a layer in which the phase transformation material is in the low temperature phase.

The thickness Lu of the high temperature layer 20u increases as the temperature Tld of the optical semiconductor element 10 increases, when the temperature of the heat dissipation member 30 is kept constant. Additionally, the thickness Lu decreases as the temperature Tld of the optical semiconductor element 10 decreases. Here, when the temperature Tld of the optical semiconductor element 10 is lower than the phase transformation temperature Tpt, the high temperature layer 20u is not present. In this case, the temperature buffer member 20 includes only the low temperature layer 20d.

The thickness Ld of the low temperature layer 20d increases as the temperature Tld of the optical semiconductor element 10 decreases, when the temperature of the heat dissipation member 30 is kept constant. Additionally, the thickness Ld decreases as the temperature Tld of the optical semiconductor element 10 increases. Here, when the temperature Tcase of the heat dissipation member 30 is higher than the phase transformation temperature Tpt, the low temperature layer 20d is not present. In this case, the temperature buffer member 20 includes only the high temperature layer 20u. The thickness Lu of the high temperature layer and the thickness Ld of the low temperature layer increase and decrease in inverse relation to each other. That is, when the thickness Lu of the high temperature layer increases, the thickness Ld of the low temperature layer decreases, and when the thickness Lu of the high temperature layer decreases, the thickness Ld of the low temperature layer increases. The sum of the thickness Ld of the high temperature layer and the thickness Lu of the low temperature layer is equal to the thickness of the temperature buffer member 20 (the distance between the first surface 20S1 and the second surface 20S2).

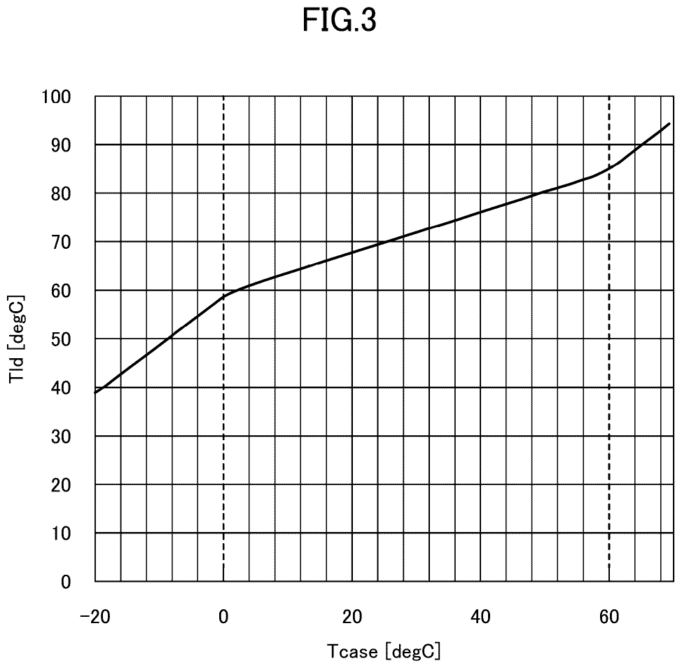

The relationship between the temperature Tld of the optical semiconductor element 10 and the temperature Tcase of the heat dissipation member 30 when the optical semiconductor element 10 is operated will be described. FIG. 3 is a graph for explaining the temperature of the temperature buffer member 20 included in the optical module 1, which is the example of the optical module according to the first embodiment.

The horizontal axis in FIG. 3 represents the temperature Tcase (unit: ° C.) of the heat dissipation member 30. The vertical axis in FIG. 3 represents the temperature Tld (unit: ° C.) of the optical semiconductor element 10. Here, it is assumed that the phase transformation temperature Tpt of the phase transformation material forming the temperature buffer member 20 is 60° C. Additionally, it is assumed that in the temperature buffer member 20, the thermal conductivity TCu of the high temperature phase (a portion where the internal temperature is higher than the phase transformation temperature Tpt) is higher than the thermal conductivity TCd of the low temperature phase (a portion where the internal temperature is lower than the phase transformation temperature Tpt).

To be precise, for example, the thermal conductivity changes in accordance with the distance from the optical semiconductor element 10 even inside the high temperature phase, and thus the value of the thermal conductivity TCu can change due to the change in the thickness Lu, but is treated as a constant value here. Similarly, the thermal conductivity TCd is treated as a constant value. In other words, the thermal resistance value TRu of the high temperature phase is lower than the thermal resistance value TRd of the low temperature phase in the temperature buffer member 20. The thermal resistance value TRu and the thermal resistance value TRd are also treated as constant values.

When the temperature Tld of the optical semiconductor element 10 is lower than 60° C., in other words, when the temperature Tcase of the heat dissipation member 30 is lower than 0° C., the temperature buffer member 20 includes only the low temperature layer 20d. Therefore, the thermal resistance of the temperature buffer member 20 is the thermal resistance when the entire phase transformation material forming the temperature buffer member 20 is in the low temperature phase. As indicated in FIG. 3, when the temperature Tld is 60° C. or lower, the thermal resistance of the temperature buffer member 20 is a constant value in the case where only the low temperature layer is present, and thus the temperature Tld of the optical semiconductor element 10 and the temperature Tcase of the heat dissipation member 30 have a proportional relationship. Here, the temperature Tld of the optical semiconductor element 10 becomes 60° C. when the temperature Tcase of the heat dissipation member 30 is 0° C., which is determined by the relationship between the amount of heat generated by the optical semiconductor element 10 and the thermal resistance of the temperature buffer member 20. For example, the temperature Tld of the optical semiconductor element 10 is calculated to be 60° C. when the temperature Tcase of the heat dissipation member 30 is 0° C., assuming that the thermal resistance of the temperature buffer member 20 is 60° C./W and the amount of heat generated by the optical semiconductor element 10 per unit time is 1 W (the same temperature is obtained even if the thermal resistance is 120° C./W and the amount of the generated heat is 0.5 W). In FIG. 2, when the area of the first surface 20S1 is equal to the area of the second surface 20S2 and the cross-sectional area of the temperature buffer member 20 between the first surface 20S1 and the second surface 20S2 is also equal to the area, the thermal resistance of the temperature buffer member 20 is obtained by multiplying the reciprocal of the heat conductivity of the temperature buffer member 20 by the length of the temperature buffer member 20 (the distance between the first surface 20S1 and the second surface 20S2) and dividing the result by the area.

When the temperature Tld of the optical semiconductor element 10 is higher than 60° C. and lower than 85° C., in other words, when the temperature Tcase of the heat dissipation member 30 is higher than 0° C. and lower than 60° C., the temperature buffer member 20 includes the high temperature layer 20u and the low temperature layer 20d.

When the temperature Tld of the optical semiconductor element 10 is 60° C., the temperature Tld of the optical semiconductor element 10 becomes equal to the phase transformation temperature Tpt of the temperature buffer member 20. Therefore, when the temperature Tld of the optical semiconductor element 10 is lower than 60° C., the temperature buffer member 20 entirely becomes the low temperature layer 20d. When the temperature Tld of the optical semiconductor element 10 is higher than 60° C., a portion of the temperature buffer member 20 close to the optical semiconductor element 10 becomes the high temperature layer 20u.

In the example of FIG. 3, when the temperature Tld of the optical semiconductor element 10 is 60° C., the temperature Tcase of the heat dissipation member 30 becomes 0° C. Whether the temperature Tld of the optical semiconductor element 10 becomes 60° C. when the temperature Tcase of the heat dissipation member 30 is 0° C. is determined by the amount of heat generated per unit time by the optical semiconductor element and the thermal resistance of the temperature buffer member 20, as described above.

The thickness of the high temperature layer 20u of the temperature buffer member 20 increases when the temperature Tcase of the heat dissipation member 30 is higher than 0° C., which results in the temperature Tld of the optical semiconductor element 10 becoming higher than the phase transformation temperature Tpt. Therefore, when the temperature Tld becomes higher than the phase transformation temperature Tpt, the thermal conductivity of the temperature buffer member 20 increases. In other words, when the temperature Tld becomes higher than the phase transformation temperature Tpt, the thermal resistance value of the temperature buffer member 20 decreases.

When the temperature Tld of the optical semiconductor element 10 is higher than 60° C. and lower than 85° C., the thermal resistance of the temperature buffer member 20 gradually decreases. Therefore, as indicated in FIG. 3, the temperature Tld of the optical semiconductor element 10 and the temperature Tcase of the heat dissipation member 30 have a proportional relationship, but the slope is less steep than that in the case where the temperature Tld of the optical semiconductor element 10 is lower than 60° C. This is because the thermal resistance value of the temperature buffer member 20 is reduced, and thus the difference between the temperature Tld of the optical semiconductor element 10 and the temperature Tcase of the heat dissipation member 30 is reduced with the temperature Tcase increasing. Here, it is assumed that the amount of heat generated by the optical semiconductor element 10 is constant regardless of the temperature Tld of the optical semiconductor element 10.

When the temperature Tcase of the heat dissipation member 30 is 60° C., the temperature Tcase of the heat dissipation member 30 becomes equal to the phase transformation temperature Tpt of the temperature buffer member 20. Therefore, in this case, the temperature buffer member 20 is entirely the high temperature layer 20u. When the temperature Tcase of the heat dissipation member 30 is lower than 60° C., a portion of the temperature buffer member 20 close to the heat dissipation member 30 becomes the low temperature layer 20d.

In the example of FIG. 3, when the temperature Tcase of the heat dissipation member 30 is 60° C., the temperature Tld of the optical semiconductor element 10 is 85° C. That is, the temperature difference between the temperature Tld of the optical semiconductor element 10 and the temperature Tcase of the heat dissipation member 30 is 25° C. This is less than half of the temperature difference of 60° C. when the temperature Tld of the optical semiconductor element 10 is 60° C. and the temperature Tcase of the heat dissipation member 30 is 0° C. The temperature Tld of the optical semiconductor element 10 when the temperature Tcase of the heat dissipation member 30 is 60° C. is determined by, for example, the thermal resistance of the temperature buffer member 20. Therefore, the decrease in the temperature difference described above is caused by the decrease in the thermal resistance of the temperature buffer member 20.

When the temperature Tcase of the second surface 20S2 is the phase transformation temperature Tpt, in the example of FIG. 3, when the temperature Tcase is 60° C., which is the phase transformation temperature Tpt, the temperature Tld of the first surface 20S1 is 85° C. That is, when the temperature Tcase of the second surface 202 is the phase transformation temperature Tpt, the temperature difference (a first temperature difference) between the temperature Tld of the first surface 20S1 and the phase transformation temperature Tpt is 25 degrees. Here, when the temperature Tcase of the second surface 20S2 is the phase transformation temperature Tpt, the temperature Tld of the first surface 201 is set to a temperature lower than the upper limit of the operating temperature (the upper limit operating temperature) of the optical semiconductor element 10.

When the temperature Tld of the first surface 20S1 is the phase transformation temperature Tpt, in the example of FIG. 3, the temperature Tcase is 0° C. That is, when the temperature Tld of the first surface 20S1 is the phase transformation temperature Tpt, the temperature difference (a second temperature difference) between the temperature Tcase of the second surface 20S2 and the phase transformation temperature Tpt is 60 degrees.

As described above, the thermal conductivity TCu of the high temperature phase becomes larger than the thermal conductivity TCd of the low temperature phase in the temperature buffer member 20, so that the first temperature difference described above becomes smaller than the second temperature difference.

When the temperature Tld of the optical semiconductor element 10 is higher than 85° C., in other words, when the temperature Tcase of the heat dissipation member 30 is higher than 60° C., the temperature Tcase of the heat dissipation member 30 becomes higher than the phase transformation temperature Tpt. Thus, when the temperature Tld of the optical semiconductor element 10 is higher than 85° C., the temperature buffer member 20 includes only the high temperature layer 20u. Therefore, the thermal resistance of the temperature buffer member 20 is the thermal resistance when the phase transformation material forming the temperature buffer member 20 is in the high temperature phase. As indicated in FIG. 3, when the temperature Tld is 85° C. or higher, the thermal resistance of the temperature buffer member 20 is a constant value, and thus the temperature Tld of the optical semiconductor element 10 and the temperature Tcase of the heat dissipation member 30 have a proportional relationship. More specifically, when the temperature Tcase of the heat dissipation member 30 changes, the temperature Tld of the optical semiconductor element 10 changes by a change amount the same as the change amount of the temperature Tcase of the heat dissipation member 30. For example, when the temperature Tcase of the heat dissipation member 30 increases by 5° C., the temperature Tld of the optical semiconductor element 10 increases by 5° C.

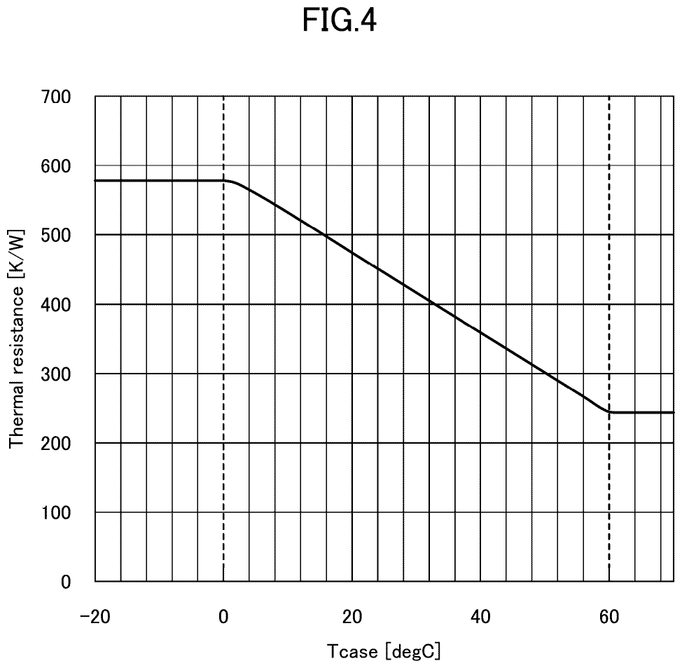

The relationship between the thermal resistance of the temperature buffer member 20 and the temperature Tcase of the heat dissipation member 30 when the optical semiconductor element 10 is operated will be described. FIG. 4 is a graph for explaining the thermal resistance of the temperature buffer member 20 included in the optical module 1, which is the example of the optical module according to the first embodiment.

The horizontal axis in FIG. 4 represents the temperature Tcase (unit: ° C.) of the heat dissipation member 30. The vertical axis in FIG. 4 represents the thermal resistance (unit: K/W) of the temperature buffer member 20. The thermal resistance represents the thermal resistance related to the heat conduction from the first surface 20S1 to the second surface 20S2 of the temperature buffer member 20. Here, the phase transformation temperature Tpt of the phase transformation material forming the temperature buffer member 20 is 60° C. Additionally, it is assumed that in the temperature buffer member 20, the thermal conductivity TCu in the high temperature phase is higher than the thermal conductivity TCd in the low temperature phase. In other words, the thermal resistance value TRu of the temperature buffer member 20 when the entire temperature buffer member 20 is in the high temperature phase is lower than the thermal resistance value TRd of the temperature buffer member 20 when the entire temperature buffer member 20 is in the low temperature phase. Here, in the temperature buffer member 20, the thermal resistance value TRd in the low temperature phase may be larger than twice the thermal resistance value TRu in the high temperature phase.

As indicated in FIG. 4, when the temperature Tcase of the heat dissipation member 30 is lower than 0° C., the thermal resistance of the temperature buffer member 20 becomes equal to the thermal resistance value TRd when the entire temperature buffer member 20 is in the low temperature phase, and becomes a constant value. Additionally, when the temperature Tcase of the heat dissipation member 30 is higher than 0° C. and lower than 60° C., the thermal resistance of the temperature buffer member 20 decreases at a constant slope with respect to the temperature Tcase. Further, when the temperature Tcase of the heat dissipation member 30 is higher than 60° C., the thermal resistance of the temperature buffer member 20 becomes equal to the thermal resistance value TRu when the entire temperature buffer member 20 is in the high temperature phase and becomes a constant value.

When the thermal resistance is constant at the thermal resistance value TRd or the thermal resistance value TRu, the temperature Tld of the optical semiconductor element 10 changes by a change amount the same as the change amount of the temperature Tcase of the heat dissipation member 30, as described above. When the thermal resistance decreases in proportion to the temperature Tcase, the temperature of the optical semiconductor element 10 changes by a change amount smaller than the change amount of the temperature Tcase of the heat dissipation member 30. For example, as indicated in FIG. 3, when the temperature Tcase of the heat dissipation member 30 increases from 0° C. to 60° C., the increase amount of the temperature Tld of the optical semiconductor element 10 is 25° C., which is smaller than the increase amount 60° C. in the temperature Tcase. Here, the numerical values described above are merely examples, and the temperature and the thermal resistance value may be appropriately determined based on the specifications of the optical module 1 and the optical semiconductor element 10.

### <Operation Result of Optical Module According to First Embodiment>

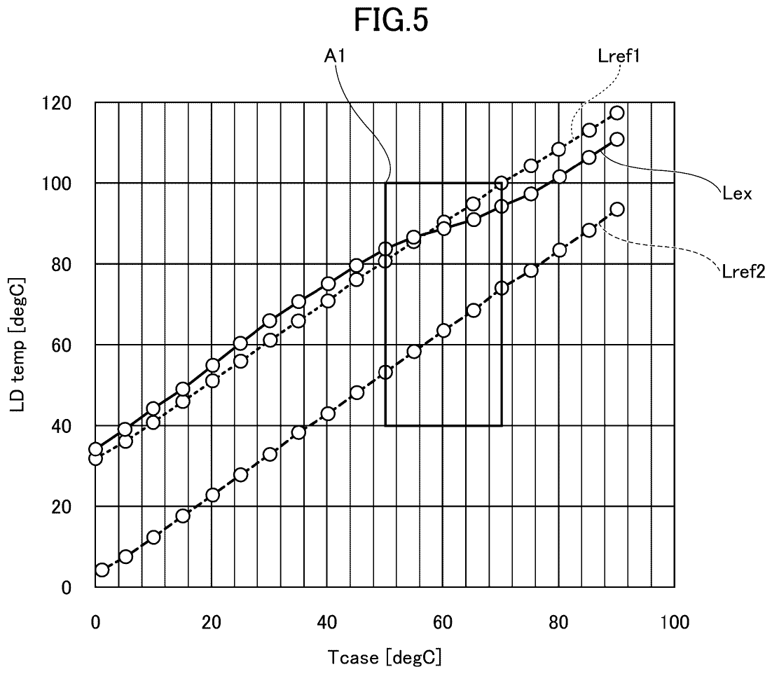

A result of operating the optical module according to the first embodiment will be described. Each of FIG. 5 to FIG. 8 is a graph for explaining an operation result of the optical module 1, which is the example of the optical module according to the first embodiment.

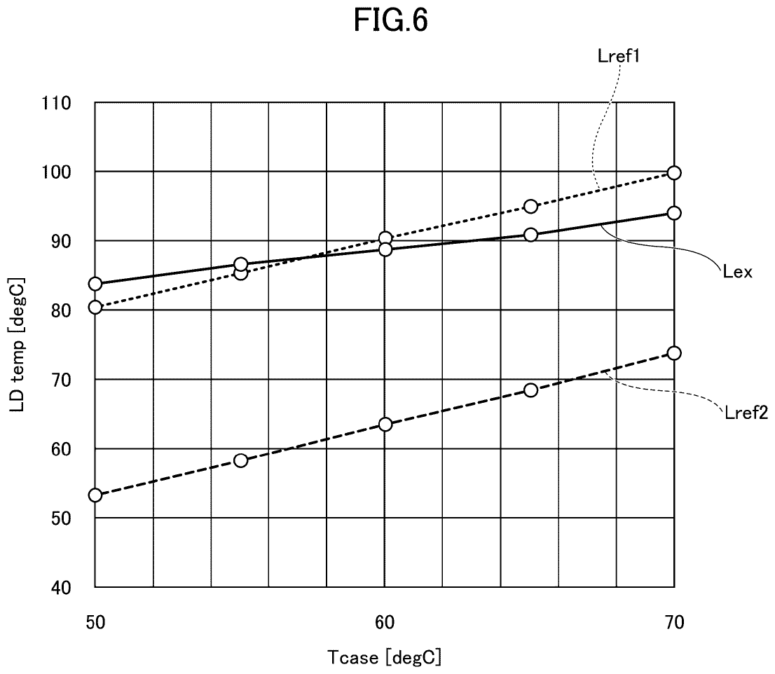

Each of FIG. 5 and FIG. 6 is a graph indicating the relationship between the temperature Tcase of the heat dissipation member 30 and the temperature Tld of the optical semiconductor element 10 when the optical module 1 is operated. FIG. 6 is an enlarged view of a region A1 in FIG. 5.

The horizontal axis in each of FIG. 5 and FIG. 6 represents the temperature Tcase (unit: ° C.) of the heat dissipation member 30. The vertical axis in each of FIG. 5 and FIG. 6 represents the temperature Tld (unit: ° C.) of the optical semiconductor element 10. A line Lex indicates a result obtained by using a silver chalcogenide (Ag₂S_{0.4}Se_{0.6}) as an example of the temperature buffer member 20. A line Lref1 indicates a result obtained by using glass instead of the temperature buffer member 20. A line Lref2 indicates a result obtained by using aluminum nitride instead of the temperature buffer member 20.

As indicated in FIG. 5 and FIG. 6, the optical module 1 can suppress the temperature rise of the temperature Tld of the optical semiconductor element 10 with respect to the temperature rise of the temperature Tcase of the heat dissipation member 30 in the temperature range from 50° C. to 70° C., for example. That is, the change in the temperature Tld of the optical semiconductor element 10 indicated by the line Lex is about half in comparison with the line Lref1 and the line Lref2.

As indicated in each of FIG. 5 and FIG. 6, when glass or aluminum nitride is used instead of the temperature buffer member 20, the temperature Tld of the optical semiconductor element 10 increases in proportion to the temperature Tcase of the heat dissipation member 30. That is, because the thermal resistance is constant, the temperature Tld of the optical semiconductor element 10 changes by the same change amount as the change amount of the temperature Tcase of the heat dissipation member 30. For example, when the temperature Tcase of the heat dissipation member 30 increases by 10° C., the temperature Tld of the optical semiconductor element 10 increases by 10° C.

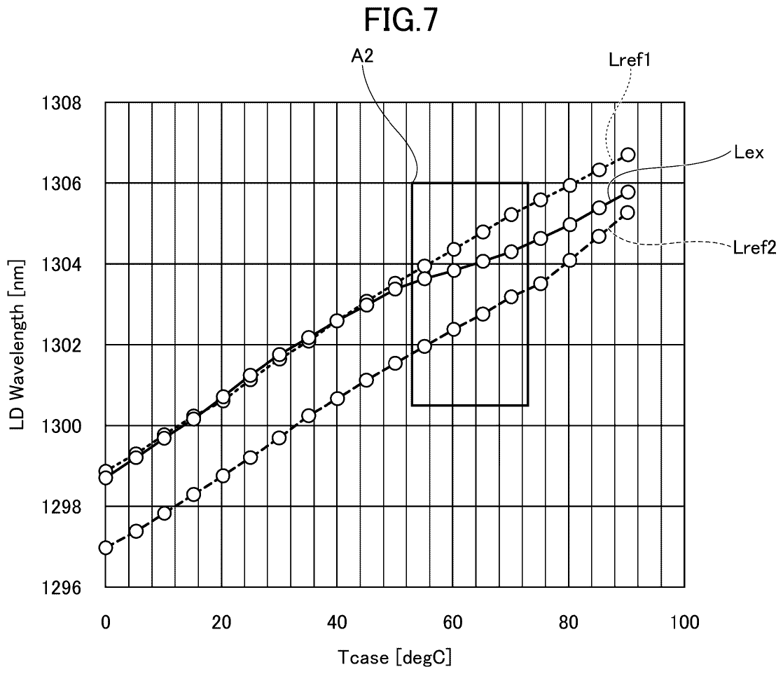

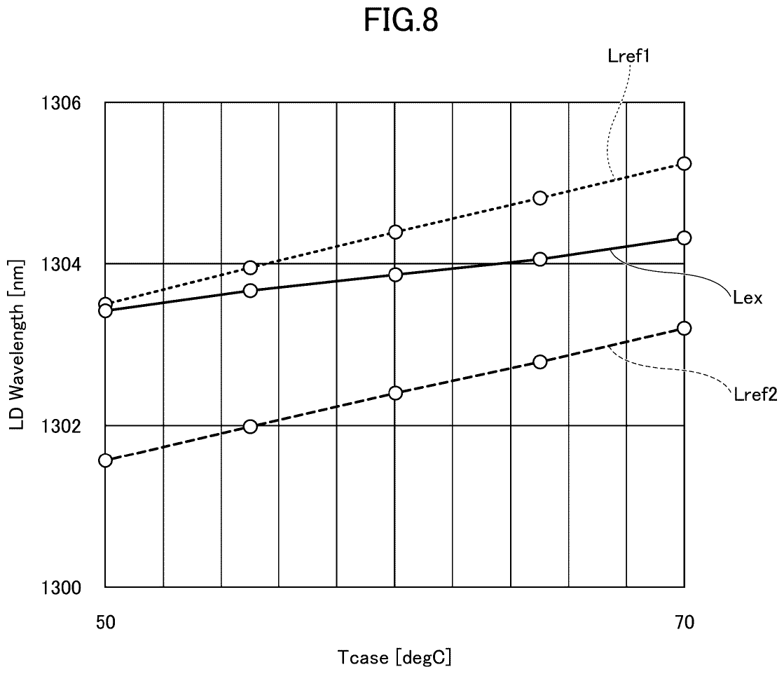

Each of FIG. 7 and FIG. 8 is a graph indicating the relationship between the temperature Tcase of the heat dissipation member 30 and the peak wavelength of the light emitted from the optical semiconductor element 10 when the optical module 1 is operated. FIG. 8 is an enlarged view of a region A2 in FIG. 7.

The horizontal axis in each of FIG. 7 and FIG. 8 represents the temperature Tcase (unit: ° C.) of the heat dissipation member 30. The vertical axis in each of FIG. 7 and FIG. 8 represents the peak wavelength (unit: nm) of the light emitted from the optical semiconductor element 10. A line Lex indicates a result obtained by using a silver chalcogenide (Ag₂S_{0.4}Se_{0.6}) as an example of the temperature buffer member 20. A line Lref1 indicates a result obtained by using glass instead of the temperature buffer member 20. A line Lref2 indicates a result obtained by using aluminum nitride instead of the temperature buffer member 20. As indicated in each of FIG. 7 and FIG. 8, the optical module 1 can reduce the change in the wavelength of the emitted light in the optical semiconductor element 10 with respect to the temperature rise of the temperature Tcase in the heat dissipation member 30 in the temperature range from 50° C. to 70° C., for example. This is because the temperature change of the temperature Tld of the optical semiconductor element 10 is reduced as described above.

As indicated in each of FIG. 7 and FIG. 8, when glass or aluminum nitride is used instead of the temperature buffer member 20, the wavelength of the emitted light in the optical semiconductor element 10 changes in proportion to the temperature Tcase in the heat dissipation member 30.

The optical module according to the first embodiment includes the temperature buffer member, thereby reducing the dissipation of the heat generated by the optical semiconductor element itself to the heat dissipation member when the operating temperature of the optical semiconductor element is low. Additionally, the optical module according to the first embodiment includes the temperature buffer member, thereby increasing the dissipation of the heat generated by the optical semiconductor element itself to the heat dissipation member when the operating temperature of the optical semiconductor element is high.

The optical module according to the first embodiment includes the temperature buffer member, thereby reducing the temperature change of the optical semiconductor element with respect to the temperature change of the heat dissipation member 30. The optical module according to the first embodiment can suppress the influence of the temperature change of the optical semiconductor element on the optical characteristics and the electrical characteristics of the optical module by reducing the temperature change in the optical semiconductor element.

With a rapid increase in a demand for data centers and a global trend toward the reduction in the environmental load in recent years, there is a demand for power consumption reduction in optical modules. In the situation where the power consumption reduction in the optical module is required, a large power consumption reduction can be expected by eliminating a temperature control component, for example, a Peltier element, which occupies a large proportion of the power consumption in the optical module.

According to the optical module of the first embodiment, the temperature buffer member is included, so that the temperature change of the optical semiconductor element can be reduced with respect to the change in the surrounding environmental temperature. The optical module according to the first embodiment can maintain the temperature of the optical semiconductor element within a predetermined range by reducing the temperature change in the optical semiconductor element without performing temperature control by cooling or heating. Additionally, the optical module according to the first embodiment includes the temperature buffer member to reduce the temperature change in the optical semiconductor element, thereby maintaining the temperature of the optical semiconductor element within a predetermined range without consuming electric power necessary for temperature control. Therefore, the optical module according to the first embodiment can maintain the operating temperature of the optical semiconductor element within a predetermined range with low power consumption. In other words, the optical module according to the first embodiment can achieve a large effect in the power consumption reduction.

An optical module according to a second embodiment includes a temperature buffer member having a first surface and a second surface opposite to the first surface, an optical semiconductor element connected to the first surface, a heater member connected to the first surface and configured to generate heat by receiving electric power from the outside, and a heat dissipation member connected to the second surface. The temperature buffer member of the optical module according to the second embodiment is formed of a phase transformation material, and the thermal conductivity of the phase transformation material changes at a phase transformation temperature.

<Configuration of Optical Module According to Second Embodiment>

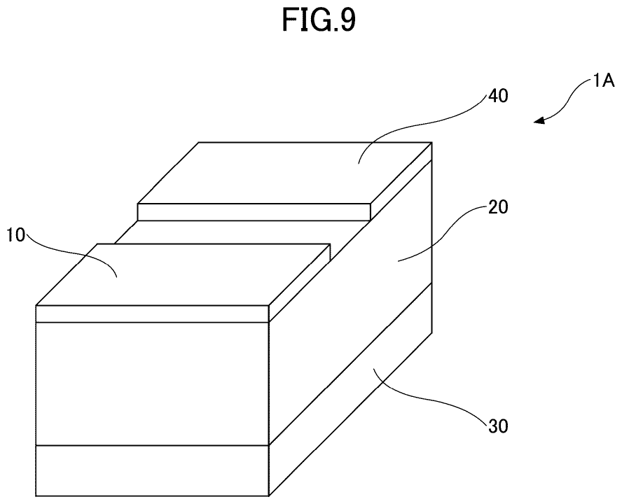

The optical module according to the second embodiment will be described using a specific example. FIG. 9 is a perspective view schematically illustrating an optical module 1A, which is an example of the optical module according to the second embodiment.

The optical module 1A includes the optical semiconductor element 10, the temperature buffer member 20, the heat dissipation member 30, and a heater member 40.

### [Optical Semiconductor Element 10]

The optical semiconductor element 10 is an element including a semiconductor configured to convert light and electricity. The optical semiconductor element 10 is substantially the same as the optical semiconductor element 10 of the first embodiment.

### [Temperature Buffer Member 20]

The temperature buffer member 20 is a member whose thermal resistance changes depending on the temperature. The temperature buffer member 20 is substantially the same as the temperature buffer member 20 of the first embodiment, but the optical semiconductor element 10 and the heater member 40 to be described later (a temperature control target 45 to be described later) are connected to the first surface 20S1, and heat generated in the temperature control target 45 is conducted.

### [Heat Dissipation Member 30]

The heat dissipation member 30 dissipates the heat generated in the temperature control target 45 to the outside. The heat dissipation member 30 is substantially the same as the heat dissipation member 30 of the first embodiment.

### [Heater Member 40]

The heater member 40 generates heat by receiving electric power from the outside. The heater member 40 is, for example, a resistance element. The heater member generates Joule heat when a current flows therethrough.

### Temperature Characteristics of Optical Module According to Second Embodiment

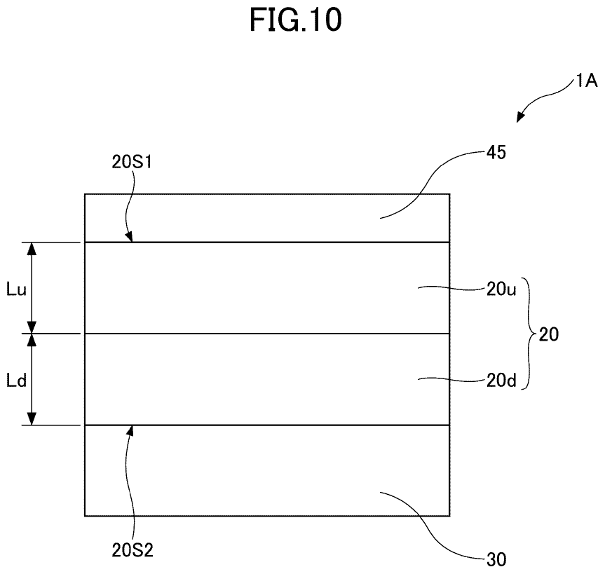

The temperature characteristics of the optical module according to the second embodiment will be described using the optical module 1A, which is the example of the optical module according to the second embodiment. FIG. 10 is a diagram for explaining a usage state of the optical module 1A, which is the example of the optical module according to the second embodiment. Here, in FIG. 10, the optical semiconductor element 10 and the heater member 40 are collectively described as the temperature control target 45. There are cases where the temperature of the optical semiconductor element 10 and the temperature of the heater member 40 are different from each other to be exact, but it is considered that each of the temperature of the optical semiconductor element 10 and the temperature of the heater member 40 is equal to the temperature of the temperature control target 45 in the following description. Here, as illustrated in FIG. 9, the heater member 40 may be disposed so as to be in contact with the temperature buffer member 20 together with the optical semiconductor element 10, or the heater member 40 may be placed on the optical semiconductor element 10 so that the optical semiconductor element 10 is sandwiched between the heater member 40 and the temperature buffer member 20.

In FIG. 10, a case where the temperature of the temperature control target 45 is higher than the temperature of the heat dissipation member 30 will be described. When the temperature control target 45 generates heat, the temperature of the temperature control target 45 becomes higher than the temperature of the heat dissipation member 30. In the configuration in which the temperature buffer member 20 is sandwiched between the temperature control target 45 and the heat dissipation member 30, the heat generated in the temperature control target 45 is transmitted from the temperature control target 45 to the heat dissipation member 30 via the temperature buffer member 20. At this time, a direction in which the heat is transmitted is the same as a direction (a first direction) in which the temperature control target 45, the temperature buffer member 20, and the heat dissipation member 30 are arranged.

When the optical module 1A is operated, the temperature of the optical semiconductor element 10 rises due to, for example, heat generated by itself. It is assumed that the heat dissipation member 30 is maintained at a substantially constant temperature. When the thermal resistance between the heat dissipation member 30 and the outside is sufficiently smaller than the thermal resistance of the temperature buffer member 20 and the heat capacity of the heat dissipation member 30 is sufficiently larger than the self-heating amount of the optical semiconductor element 10, the temperature change of the heat dissipation member 30 can be ignored, for example. Here, it is considered that the temperature of the heat dissipation member 30 is substantially equal to the external temperature (for example, the case temperature of the body or the surrounding environmental temperature around the optical module 1A). The heater member 40 heats the optical semiconductor element 10 so that the temperature (the operating temperature) of the optical semiconductor element 10 is kept constant. For example, when the operating temperature of the optical semiconductor element 10 is 50° C., the heat is generated in the heater member 40 to heat the optical semiconductor element 10 so that the operating temperature is increased by 40° C. to 90° C. Additionally, for example, when the operating temperature of the optical semiconductor element 10 is 70° C., the heat generated in the heater member 40 to heat the optical semiconductor element 10 so that the operating temperature is increased by 20° C. to 90° C. As described above, when the temperature of the optical semiconductor element 10 is kept constant by the heat generated in the heater member 40, the temperature of the temperature control target 45 is substantially equal to the operating temperature of the optical semiconductor element 10.

The temperature of the temperature control target 45 is represented by the temperature Tld, and the temperature of the heat dissipation member 30 is represented by the temperature Tcase. The temperature Tld of the temperature control target 45 is, for example, the temperature of the surface of the temperature control target 45 that is in contact with the first surface 20S1. The temperature Tcase of the heat dissipation member 30 is, for example, the temperature of the surface of the heat dissipation member 30 that is in contact with the second surface 20S2. The phase transformation temperature of the phase transformation material forming the temperature buffer member 20 is represented by the phase transformation temperature Tpt. As the temperature condition, a case where the phase transformation temperature Tpt is higher than the temperature Tcase of the heat dissipation member 30 and lower than the temperature Tld of the temperature control target 45 is assumed.

In the optical module 1A, the temperature of the inside of the temperature buffer member 20 (the internal temperature) between the temperature control target 45 and the heat dissipation member 30 is considered to change in accordance with the distance from the temperature control target 45. That is, the internal temperature increases as the position is closer to the temperature control target 45, and decreases as the position is farther from the temperature control target 45. Therefore, as illustrated in FIG. 10, the temperature buffer member 20 is separated into the high temperature layer 20u and the low temperature layer 20d. The high temperature layer 20u is a layer of the temperature buffer member 20 having a temperature higher than the phase transformation temperature Tpt. In other words, the high temperature layer 20u is a layer in which the phase transformation material is in a high temperature phase. The low temperature layer 20d is a layer of the temperature buffer member 20 having a temperature lower than the phase transformation temperature Tpt. In other words, the low temperature layer 20d is a layer in which the phase transformation material is in a low temperature phase.

The thickness Lu of the high temperature layer 20u increases as the temperature Tld of the temperature control target 45 increases when the temperature of the heat dissipation member 30 is kept constant. Additionally, the thickness Lu decreases as the temperature Tld of the temperature control target 45 decreases. Here, when the temperature Tld of the temperature control target 45 is lower than the phase transformation temperature Tpt, the high temperature layer 20u in the temperature buffer member 20 is not present. In this case, when the temperature Tld of the temperature control target 45 becomes lower than the phase transformation temperature Tpt, the temperature buffer member 20 includes only the low temperature layer 20d.

The thickness Ld of the low temperature layer 20d increases as the temperature Tld of the temperature control target 45 decreases. Additionally, the thickness Ld decreases as the temperature Tld of the temperature control target 45 increases. Here, when the temperature Tcase of the heat dissipation member 30 is higher than the phase transformation temperature Tpt due to heat from the temperature control target 45, the low temperature layer 20d in the temperature buffer member 20 is not present. In this case, when the temperature Tcase of the heat dissipation member 30 becomes higher than the phase transformation temperature Tpt, the temperature buffer member 20 includes only the high temperature layer 20u. The thickness Lu of the high temperature layer and the thickness Ld of the low temperature layer increase and decrease in inverse relation to each other. That is, when the thickness Lu of the high temperature layer increases, the thickness Ld of the low temperature layer decreases, and when the thickness Lu of the high temperature layer decreases, the thickness Ld of the low temperature layer increases. The sum of the thickness Ld of the high temperature layer and the thickness Lu of the low temperature layer is equal to the thickness of the temperature buffer member 20 (the distance between the first surface 20S1 and the second surface 20S2).

The relationship between the temperature Tld of the temperature control target 45 and the temperature Tcase of the heat dissipation member 30 when the optical semiconductor element 10 and the heater member 40 are operated is substantially the same as the relationship between the temperature Tld of the optical semiconductor element 10 and the temperature Tcase of the heat dissipation member 30 when the optical semiconductor element 10 of the first embodiment in FIG. 3 is operated.

### Functional Configuration of Optical Module According to Second Embodiment

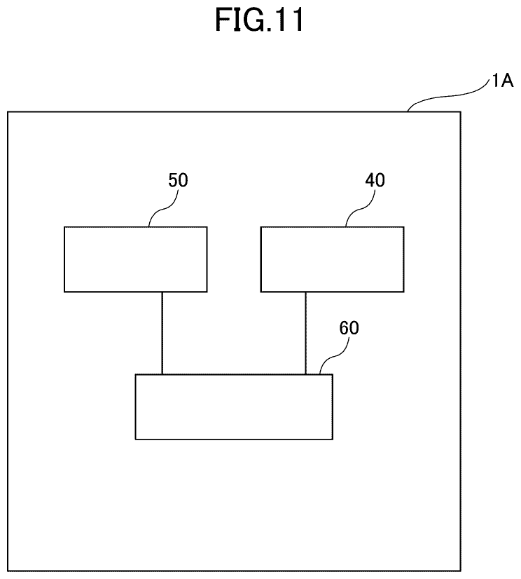

With respect to the optical module according to the second embodiment, a function of adjusting the temperature of the optical semiconductor element will be described. FIG. 11 is a diagram for explaining an outline of a functional configuration of the optical module 1A, which is the example of the optical module according to the second embodiment.

The optical module 1A further includes a temperature detection element 50 and a controller 60. Here, the controller 60 may be provided outside the optical module 1A.

### [Temperature Detection Element 50]

The temperature detection element 50 is an element for measuring the temperature in the vicinity of the optical semiconductor element 10. The temperature detection element 50 is, for example, a thermistor, a resistance temperature detector, or a thermocouple.

### [Controller 60]

The controller 60 controls the heater member 40 based on the temperature detected by the temperature detection element 50 so that the temperature of the optical semiconductor element 10 is within a desired range. For example, the controller 60 calculates the temperature of the optical semiconductor element 10 based on a change in the resistance value of the temperature detection element 50. For example, the controller 60 adjusts electric power to be supplied to the heater member 40 by, for example, proportional-integral-differential (PID) control so that the temperature of the optical semiconductor element 10 is within a desired range. The controller 60 causes the heater member 40 to generate heat by, for example, applying a predetermined voltage to the heater member 40 to cause a predetermined current to flow.

The controller 60 may control the heater member 40 so that the temperature Tld of the first surface 20S1 observed when the temperature Tcase of the second surface 20S2 is equal to the phase transformation temperature Tpt is maintained, for example. In other words, the controller 60 may control the heater member 40 so that the temperature Tld of the first surface 20S1 is maintained at the temperature Tld of the first surface 20S1 observed when the temperature Tcase of the second surface 20S2 is equal to the phase transformation temperature Tpt, when the temperature Tcase of the second surface 20S2 becomes lower than the phase transformation temperature Tpt. With this, for example, even when the temperature Tcase of the second surface 20S2 changes, the temperature Tld of the first surface 20S1 can be maintained at the temperature Tld=85° C. of the first surface 20S1 observed when the temperature Tcase of the second surface 20S2 is equal to the phase transformation temperature Tpt=60° C.

### Operation Result of Optical Module According to Second Embodiment

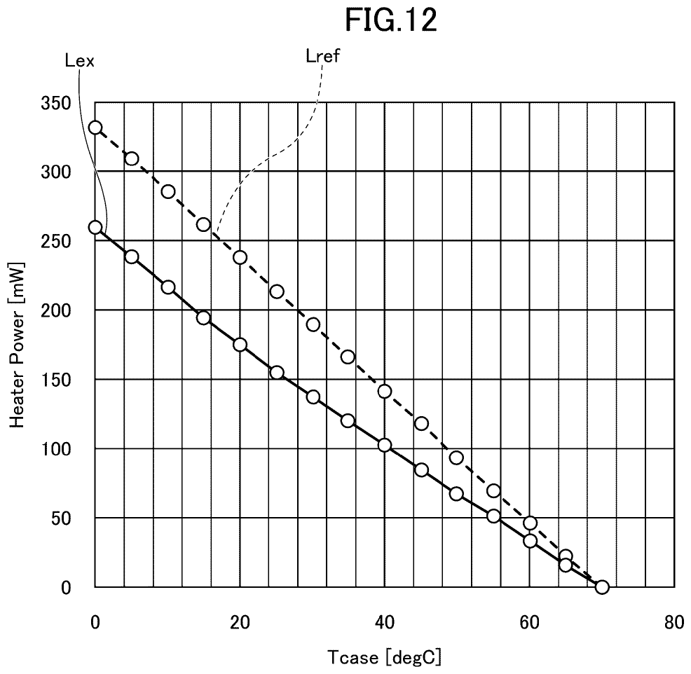

A result of operating the optical module according to the second embodiment will be described. FIG. 12 is a graph for explaining an operation of the optical module 1A, which is the example of the optical module according to the second embodiment.

FIG. 12 is a graph indicating a relationship between the temperature Tcase of the heat dissipation member 30 and the electric power (unit: mW) supplied to the heater member 40 when the optical module 1A is operated. Here, the electric power is controlled so that the temperature of the optical semiconductor element 10 becomes 90° C. The optical semiconductor element 10 generates heat by consuming the electric power during the operation. For example, if the temperature of the optical semiconductor element 10 becomes 90° C. due to self-heating of the optical semiconductor element 10 when the temperature Tcase is 70° C., the temperature of the optical semiconductor element 10 becomes lower than 90° C. when the temperature Tcase becomes lower than 70° C., and therefore the heater member 40 is caused to generate heat to maintain the temperature of the optical semiconductor element 10 at 90° C. As the temperature Tcase decreases, the electric power of the heater member 40 increases in order to increase the amount of heat generated by the heater member 40.

The horizontal axis of FIG. 12 represents the temperature Tcase (unit: ° C.) of the heat dissipation member 30. The vertical axis of FIG. 12 represents the power (unit: mW) supplied to the heater member 40. A line Lex indicates a result obtained by using a silver chalcogenide (Ag₂S_{0.4}Se_{0.6}) as an example of the temperature buffer member 20. A line Lref indicates a result obtained when glass is used instead of the temperature buffer member 20.

As indicated in FIG. 12, the optical module 1A can reduce the power consumption of the heater member 40 in comparison with the case where glass is used instead of the temperature buffer member 20, for example, in a case where the temperature of the optical semiconductor element 10 is controlled in the temperature range of 70° C. or lower.

The optical module 1A according to the second embodiment includes the temperature buffer member 20. As the temperature Tcase decreases, the thermal resistance of the temperature buffer member 20 increases as indicated in FIG. 4. With this, when the temperature Tcase of the optical module is lower than the phase transformation temperature Tpt, the temperature of the optical semiconductor element 10 can be efficiently increased by the heat generated by the heater member 40. Therefore, the optical module 1A according to the second embodiment can reduce the electric power required for heating by the heater member 40 when the temperature Tcase of the optical module 1A is lower than the phase transformation temperature Tpt, in comparison with the case where the temperature buffer member 20 is not used. Additionally, the optical module 1A according to the second embodiment includes the temperature buffer member 20. When the temperature Tcase of the optical semiconductor element 10 is higher than the phase transformation temperature Tpt, the thermal resistance of the temperature buffer member 20 is reduced, thereby promoting the heat dissipation member 30 to dissipate the heat generated by the optical semiconductor element 10 itself. This can suppress an excessive rise in the operating temperature of the optical semiconductor element 10.

The optical module 1A according to the second embodiment includes the temperature buffer member 20, thereby suppressing the electric power required for adjusting the temperature of the optical semiconductor element 10. In particular, when the temperature of the optical semiconductor element 10 is maintained at a predetermined value by the heat generated by the heater member 40, the electric power can be reduced more as the temperature of the optical module 1A becomes lower.

With a rapid increase in a demand for data centers and a global trend toward the reduction in the environmental load in recent years, there is a demand for power consumption reduction in optical modules. Reducing the power consumption required for the temperature control of the optical module greatly contributes to the reduction in power consumption of the optical module.

According to the optical module of the second embodiment, the temperature buffer member is included, thereby suppressing power consumption when the temperature of the optical semiconductor element is controlled. The optical module according to the second embodiment can achieve a large effect of reducing power consumption by suppressing power consumption when the temperature of the optical semiconductor element is controlled.

### Modified Example

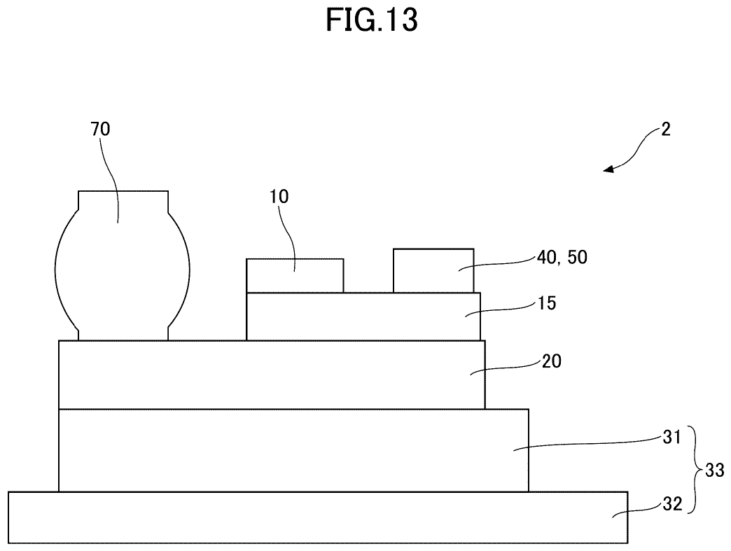

A modified example of the optical module according to the second embodiment will be described. FIG. 13 is a diagram for explaining an optical module 2 as an example of the optical module according to the second embodiment.

The optical module 2 includes the optical semiconductor element 10, a carrier 15, the temperature buffer member 20, a heat dissipation member 33, the heater member 40, the temperature detection element 50, and a lens 70. The optical semiconductor element 10, the temperature buffer member 20, the heater member 40, and the temperature detection element 50 have been described above, and thus detailed description thereof will be omitted.

### [Carrier 15]

The carrier 15 is a substrate on which the optical semiconductor element 10, the heater member 40, and the temperature detection element 50 are mounted. The carrier 15 is formed of, for example, a material having a low electrical conductivity and a high thermal conductivity. More specifically, the carrier 15 is formed of aluminum nitride. The carrier 15 is connected to the temperature buffer member 20. The carrier 15 corresponds to the temperature control target 45 illustrated in FIG. 10.

### [Heat Dissipation Member 33]

The heat dissipation member 33 dissipates heat generated in the optical semiconductor element 10. The heat dissipation member 33 includes a plate 31 and a package 32. The plate 31 is connected to the temperature buffer member 20. The package 32 is connected to the plate 31.

The plate 31 is formed of, for example, aluminum nitride. The package 32 is formed of, for example, aluminum nitride. The plate 31 and the package 32 may be integrally formed (may be formed from a monolithic structure).

### [Lens 70]

The lens 70 converts light emitted from the optical semiconductor element 10 into parallel light, for example. Additionally, the lens 70 condenses light from the outside onto the optical semiconductor element 10. The lens 70 is formed of, for example, glass or resin.

The lens 70 is mounted on the temperature buffer member 20, for example.

The embodiments disclosed herein should be considered as illustrative and not restrictive in all respects. The scope of the present invention is defined by the appended claims rather than the foregoing description, and is intended to include all modifications within the scope and meaning equivalent to the appended claims.

What is claimed is:

1. An optical module comprising:
a temperature buffer member having a first surface and a second surface opposite to the first surface;
an optical semiconductor element that is connected to the first surface and that generates heat by itself; and
a heat dissipation member connected to the second surface,
wherein the temperature buffer member is formed of a phase transformation material, a thermal conductivity of the phase transformation material changing at a phase transformation temperature.

2. The optical module as claimed in claim 1, wherein a thermal conductivity of the heat dissipation member is larger than a thermal conductivity of the temperature buffer member.

3. The optical module as claimed in claim 2,
wherein the first surface has a first temperature higher than the phase transformation temperature when a temperature of the second surface is equal to the phase transformation temperature,
wherein the second surface has a second temperature lower than the phase transformation temperature when a temperature of the first surface is equal to the phase transformation temperature, and
wherein a first temperature difference between the first temperature and the phase transformation temperature is set to be smaller than a second temperature difference between the phase transformation temperature and the second temperature.

4. The optical module as claimed in claim 3, wherein the first temperature is set to a temperature lower than an upper limit operating temperature of the optical semiconductor element.

5. The optical module as claimed in claim 3, wherein the temperature buffer member has a first thermal resistance between the first surface and the second surface when the temperature of the second surface is equal to the phase transformation temperature, and has a second thermal resistance between the first surface and the second surface when the temperature of the second surface is equal to the second temperature, the second thermal resistance being larger than the first thermal resistance.

6. The optical module as claimed in claim 5, wherein a resistance value of the second thermal resistance is greater than twice a resistance value of the first thermal resistance.

7. The optical module as claimed in claim 1, wherein the phase transformation temperature of the phase transformation material is 70° C. or greater and 100° C. or less.

8. The optical module as claimed in claim 1, wherein the phase transformation material includes any one of silver sulfide, a silver chalcogenide, or copper gallium telluride.

9. The optical module as claimed in claim 1, further comprising any one of heat dissipation grease, solder, or metallic paste between the second surface of the temperature buffer member and the heat dissipation member.

10. An optical module comprising:
a temperature buffer member having a first surface and a second surface opposite to the first surface;
an optical semiconductor element connected to the first surface;
a heater member connected to the first surface and configured to generate heat by receiving electric power from outside; and
a heat dissipation member connected to the second surface,
wherein the temperature buffer member is formed of a phase transformation material, a thermal conductivity of the phase transformation material changing at a phase transformation temperature.

11. The optical module as claimed in claim 10, wherein a thermal conductivity of the heat dissipation member is larger than a thermal conductivity of the temperature buffer member.

12. The optical module as claimed in claim 10,
wherein the first surface has a first temperature higher than the phase transformation temperature when a temperature of the second surface is equal to the phase transformation temperature, and
wherein a temperature of the first surface is maintained at the first temperature by adjusting the electric power of the heater member when the temperature of the second surface is less than the phase transformation temperature.

13. The optical module as claimed in claim 12, wherein the first temperature is set to a temperature lower than an upper limit operating temperature of the optical semiconductor element.

14. The optical module as claimed in claim 12,
wherein the second surface has a second temperature lower than the phase transformation temperature when the temperature of the first surface is equal to the phase transformation temperature, and
wherein the temperature buffer member has a first thermal resistance between the first surface and the second surface when the temperature of the second surface is equal to the phase transformation temperature, and has a second thermal resistance between the first surface and the second surface when the temperature of the second surface is equal to the second temperature, the second thermal resistance being larger than the first thermal resistance.

15. The optical module as claimed in claim 14, wherein a resistance value of the second thermal resistance is greater than twice a resistance value of the first thermal resistance.

16. The optical module as claimed in claim 10, wherein the phase transformation temperature of the phase transformation material is 70° C. or greater and 100° C. or less.

17. The optical module as claimed in claim 10, wherein the phase transformation material includes any one of silver sulfide, a silver chalcogenide, or copper gallium telluride.

18. The optical module as claimed in claim 10, further comprising a temperature detection element connected to the first surface and configured to generate a detection signal in accordance with a temperature of the first surface.
